(19) United States
(12) Patent Application Publication
(10) Pub. No.: US 2026/0032980 A1
(43) Pub. Date: Jan. 29, 2026

(54) NANOSHEETS WITH HIDDEN SPACER

(71) Applicant: International Business Machines Corporation, Armonk, NY (US)

(72) Inventors: Effendi Leobandung, Stormville, NY (US); Tze-chiang Chen, Yorktown Heights, NY (US)

(21) Appl. No.: 18/780,586

(22) Filed: Jul. 23, 2024

(51) Int. Cl. H01L 29/417; H01L 21/311; H01L 29/06; H01L 29/423; H01L 29/66; H01L 29/775; H01L 29/786

(52) U.S. Cl. CPC H10D 64/258; H01L 21/31116; H10D 62/116; H10D 64/015; H10D 30/014; H10D 30/43; H10D 30/6735; H10D 30/6757; H10D 62/121; H10D 64/017

(57) ABSTRACT

Embodiments of the invention include a semiconductor structure having nanosheets formed over a substrate and connected to source/drain regions, the nanosheets including a bottom nanosheet. Hidden spacers are formed between and below the nanosheets, where a bottom hidden spacer of the hidden spacers is a single continuous piece formed on the substrate and extending up the source/drain regions to the bottom nanosheet. Gate material is formed on the nanosheets and the hidden spacers.

### BACKGROUND

The present invention generally relates to fabrication methods and resulting structures for integrated circuits (ICs), and more specifically, to fabrication methods and resulting structures configured and arranged for providing nanosheets with hidden spacers.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. on the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device that shows promise for advanced integrated circuit products is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

### SUMMARY

Embodiments of the present invention are directed to providing nanosheets with hidden spacers. A semiconductor structure includes nanosheets formed over a substrate and connected to source/drain regions, the nanosheets having a bottom nanosheet. The semiconductor structure includes hidden spacers formed between and below the nanosheets, where a bottom hidden spacer of the hidden spacers is a single continuous piece formed on the substrate and extending up the source/drain regions to the bottom nanosheet. The semiconductor structure includes a gate material formed on the nanosheets and the hidden spacers.

According to one or more embodiments, a semiconductor structure includes nanosheets formed over a substrate and connected to source/drain regions, the nanosheets having a bottom nanosheet. The semiconductor structure includes hidden spacers formed between and below the nanosheets, where a bottom hidden spacer of the hidden spacers is a single continuous piece formed on the substrate and extending up the source/drain regions to the bottom nanosheet, where the bottom hidden spacer comprises a cavity below the bottom nanosheet. The semiconductor structure includes a gate material formed on the nanosheets and the hidden spacers, the gate material filling the cavity of the bottom hidden spacer.

According to one or more embodiments, a method includes forming nanosheets having sacrificial layers and semiconductor layers, replacing the sacrificial layers with hidden spacers, patterning the nanosheets and the hidden spacers, and forming source/drain regions connected to the nanosheets and the hidden spacers. The method includes etching portions of the hidden spacers and forming gate material on the nanosheets and the hidden spacers.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A and 1B respectively depict a top view and a cross-sectional view of a portion of an integrated circuit (IC) under-fabrication after fabrication operations according to one or more embodiments of the invention;

FIGS. 2A, 2B, and 2C depict a top view and cross-sectional views of a portion of an IC under-fabrication after fabrication operations according to one or more embodiments of the invention;

FIGS. 3A and 3B depict a top view and a cross-sectional view of a portion of an IC under-fabrication after fabrication operations according to one or more embodiments of the invention;

FIGS. 4A and 4B depict a top view and a cross-sectional view of a portion of an IC under-fabrication after fabrication operations according to one or more embodiments of the invention;

FIGS. 5A and 5B depict a top view and a cross-sectional view of a portion of an IC under-fabrication after fabrication operations according to one or more embodiments of the invention;

FIGS. 6A and 6B depict a top view and a cross-sectional view of a portion of an IC under-fabrication after fabrication operations according to one or more embodiments of the invention;

FIGS. 7A and 7B depict a top view and a cross-sectional view of a portion of an IC under-fabrication after fabrication operations according to one or more embodiments of the invention;

FIGS. 8A and 8B depict a top view and a cross-sectional view of a portion of an IC under-fabrication after fabrication operations according to one or more embodiments of the invention;

FIGS. 9A and 9B depict a top view and a cross-sectional view of a portion of an IC under-fabrication after fabrication operations according to one or more embodiments of the invention;

FIGS. 10A and 10B depict a top view and a cross-sectional view of a portion of an IC under-fabrication after fabrication operations according to one or more embodiments of the invention;

FIGS. 11A and 11B depict a top view and a cross-sectional view of a portion of an IC under-fabrication after fabrication operations according to one or more embodiments of the invention;

FIGS. 12A and 12B depict a top view and a cross-sectional view of a portion of an IC under-fabrication after fabrication operations according to one or more embodiments of the invention;

FIG. 13 depicts a flowchart of a method of forming a semiconductor structure according to one or more embodiments of the invention; and

FIG. 14 depicts a flowchart of a method of forming a semiconductor structure according to one or more embodiments of the invention.

### DETAILED DESCRIPTION

Embodiments of the present disclosure are directed to a semiconductor structure. The semiconductor structure includes nanosheets formed over a substrate and connected to source/drain regions, the nanosheets having a bottom nanosheet. The semiconductor structure includes hidden spacers formed between and below the nanosheets, where a bottom hidden spacer of the hidden spacers is a single continuous piece formed on the substrate and extending up the source/drain regions to the bottom nanosheet. The semiconductor structure includes gate material formed on the nanosheets and the hidden spacers. As technical effects and technical solutions, the present disclosure provides an early release of the sacrificial layers. This removes the need for indenting the inner spacers because inner spacer indentation and formation are becoming a yield issue to the nanosheet transistors. This also provides better performance. The single continuous bottom hidden spacer as a bottom dielectric isolation reduces the source/drain epitaxial etch out defect.

In addition to one or more of the features described above or below, or as an alternative, further embodiments disclose the bottom hidden spacer extends a length of the bottom nanosheet. Technical effects and solutions include the bottom hidden spacer being a continuous piece for isolating the nanosheets.

In addition to one or more of the features described above or below, or as an alternative, further embodiments disclose the hidden spacers include at least one other hidden spacer and the bottom hidden spacer, the bottom hidden spacer having a thickness greater than the at least one other hidden spacer. Technical effects and solutions include the bottom hidden spacer being able to serve as hidden spacers and an isolation layer.

In addition to one or more of the features described above or below, or as an alternative, further embodiments disclose the hidden spacers include at least one other hidden spacer and the bottom hidden spacer, the bottom hidden spacer having a length greater than the at least one other hidden spacer. Technical effects and solutions include the bottom hidden spacer being able to serve as hidden spacers and an isolation layer.

In addition to one or more of the features described above or below, or as an alternative, further embodiments disclose the gate material is formed on a top surface of the bottom hidden spacer. Technical effect and solutions include the bottom hidden spacer being able to serve as hidden spacers and an isolation layer.

In addition to one or more of the features described above or below, or as an alternative, further embodiments disclose the bottom hidden spacer includes a cavity, and the gate material is formed in the cavity between the top surface of the bottom hidden spacer and a bottom surface of the bottom nanosheet. Technical effect and solutions include the bottom hidden spacer being able to serve as hidden spacers and an isolation layer.

In addition to one or more of the features described above or below, or as an alternative, further embodiments disclose the hidden spacers include at least one other hidden spacer and the bottom hidden spacer, the at least one other hidden spacer having a triangular shape extending away from the source/drain regions. Technical effect and solutions include hidden spacers formed early without indenting the sacrificial layers.

In addition to one or more of the features described above or below, or as an alternative, further embodiments disclose the bottom hidden spacer extends between the source/drain regions. Technical effects and solutions include the bottom hidden spacer being a continuous piece for isolating the nanosheets.

Embodiments disclose a method including forming nanosheets over a substrate, the nanosheets including a bottom nanosheet and being connected to source/drain regions. The method includes forming hidden spacers between and below the nanosheets, where a bottom hidden spacer of the hidden spacers is a single continuous piece formed on the substrate and extending up the source/drain regions to the bottom nanosheet. The method includes forming gate material on the nanosheets and the hidden spacers. As technical effects and technical solutions, the present disclosure provides an early release of the sacrificial layers. This removes the need for indenting the inner spacers because inner spacer indentation and formation is becoming a yield issue to the nanosheet transistor. This also provides better performance. The single continuous bottom hidden spacer as a bottom dielectric isolation reduces the source/drain epitaxial etch out defect.

In addition to one or more of the features described above or below, or as an alternative, further embodiments disclose the nanosheets include alternating layers of sacrificial layers and semiconductor layers and forming the hidden spacers between and below the nanosheets include completely removing the sacrificial layers so as to leave cavities such that the hidden spacers are formed in the cavities. As technical effects and technical solutions, the present disclosure provides an early release of the sacrificial layers, resulting in the bottom hidden spacer being a continuous piece for isolating the nanosheets.

Embodiments disclose a semiconductor structure having nanosheets formed over a substrate and connected to source/drain regions, the nanosheets comprising a bottom nanosheet. The semiconductor structure includes hidden spacers formed between and below the nanosheets, where a bottom hidden spacer of the hidden spacers is a single continuous piece formed on the substrate and extending up the source/drain regions to the bottom nanosheet, where the bottom hidden spacer comprises a cavity below the bottom nanosheet. The semiconductor structure includes a gate material formed on the nanosheets and the hidden spacers, the gate material filling the cavity of the bottom hidden spacer. As technical effects and technical solutions, the present disclosure provides an early release of the sacrificial layers. This removes the need for indenting the inner spacers because inner spacer indentation and formation are becoming a yield issue to the nanosheet transistor. This also provides better performance. The single continuous bottom hidden spacer as a bottom dielectric isolation reduces the source/drain epitaxial etch out defect.

In addition to one or more of the features described above or below, or as an alternative, further embodiments disclose the gate material is formed in the cavity between the top surface of the bottom hidden spacer and a bottom surface of the bottom nanosheet. Technical effect and solutions include the bottom hidden spacer being able to serve as hidden spacers and an isolation layer.

Embodiments disclose a method including forming nanosheets having sacrificial layers and semiconductor layers, replacing the sacrificial layers with hidden spacers, patterning the nanosheets and the hidden spacers, and forming source/drain regions connected to the nanosheets and the hidden spacers. The method includes etching portions of the hidden spacers and forming gate material on the nanosheets and the hidden spacers. As technical effects and technical solutions, the present disclosure provides an early release of the sacrificial layers. This removes the need for indenting the inner spacers because inner spacer indentation and formation are becoming a yield issue to the nanosheet transistor. This also provides better performance. The single continuous bottom hidden spacer as a bottom dielectric isolation reduces the source/drain epitaxial etch out defect.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The MOSFET is a transistor used for amplifying or switching electronic signals. The MOSFET has a source, a drain, and a metal gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (NFET) and p-type field effect transistors (PFET) are two types of complementary MOSFETs. The NFET includes n-doped source and drain junctions and uses electrons as the current carriers. The PFET includes p-doped source and drain junctions and uses holes as the current carriers.

The nanowire or nanosheet MOSFET is a type of MOSFET that uses multiple stacked nanowires/nanosheets to form multiple channel regions. The gate regions of a nanosheet MOSFET are formed by wrapping gate stack materials around the multiple nanowire/nanosheet channels. This configuration is known as a gate-all-around (GAA) FET structure. The nanowire/nanosheet MOSFET device mitigates the effects of short channels and reduces drain-induced barrier lowering.

The GAA nanosheet FET structures can provide superior electrostatics. In contrast to known Fin-type FET (FinFET) structures in which the fin element of the transistor extends “up” out of the transistor, nanosheet FET designs implement the fin as a silicon nanosheet/nanowire. In a known configuration of a GAA nanosheet FET, a relatively small FET footprint is provided by forming the channel region as a series of nanosheets (i.e., silicon nanowires). A known GAA configuration includes a source region, a drain region, and stacked nanosheet channels between the source and drain regions. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized.

One or more embodiments provide transistors having nanosheets with hidden spacers. A stack of nanosheets and silicon germanium sacrificial layers is formed, and a dummy gate is formed. An early release of the silicon germanium sacrificial layers is performed, and the sacrificial layers are replaced with insulator layers as hidden spacers. After patterning, source/drain regions are formed, and the dummy gate is removed. Anisotropic etching is performed to selectively remove portions of the hidden spacers, and the gate material is deposited in cavities formed after removing portions of the hidden spacers.

As technical benefits and solutions, this removes the need for indenting the inner spacers because inner spacer indentation and formation are becoming a yield issue and limits contacted gate (poly) pitch (CPP) scaling. This also provides better performance. Further, the hidden spacer is formed post channel release to reduce the source/drain epitaxial etch out defect. The single continuous bottom hidden spacer serving as a bottom dielectric isolation layer reduces the source/drain epitaxial etch out defect. Further, there is no dimple hidden spacer from lack of hidden spacer deposition and etch back.

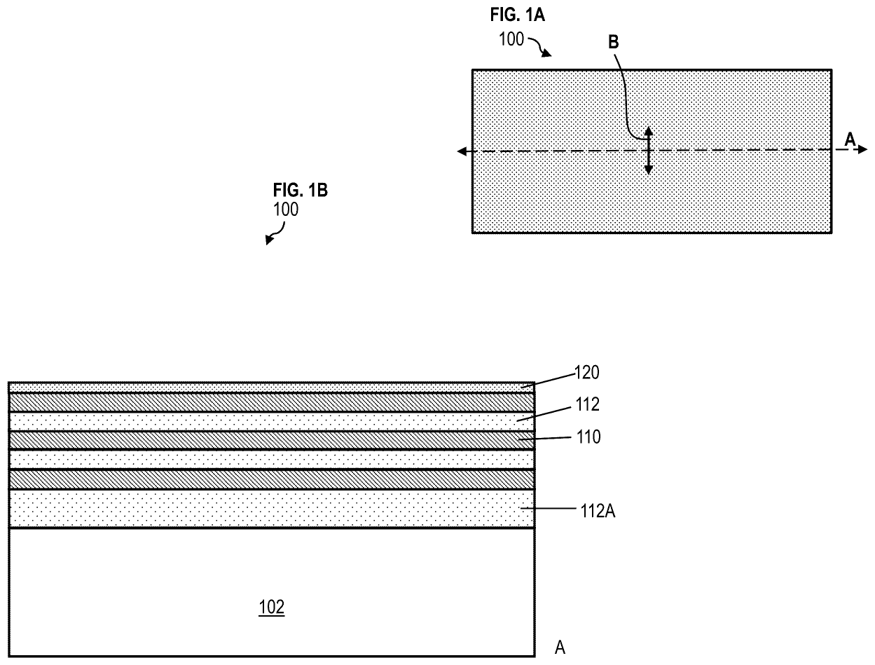

Turning now to a more detailed description of aspects of the present invention, FIG. 1A depicts a top view of a simplified illustration of a portion of an integrated circuit (IC) 100, and FIG. 1B depicts a cross-sectional view taken along A of the IC 100. For ease of understanding, some layers may be omitted from the top view so as not to obscure the figure and to view layers underneath. As such, the top view is intended to provide a simplified illustration and a general orientation, but the top view is not intended to be a complete representation of the device. Standard semiconductor fabrication techniques can be utilized to fabricate the IC 100 as understood by one of ordinary skill in the art. Any suitable lithography processes including deposition techniques and etching techniques can be utilized herein.

FIGS. 1A and 1B depict the IC 100 having a wafer where several fabrication processes have been performed. The figures illustrate the IC 100 after nanosheet stack growth with alternating nanosheets. A nanosheet stack is formed on a substrate 102 (or wafer). The substrate 102 may be formed of (pure) silicon. Other suitable semiconductor materials can be utilized for the substrate 102. As seen in FIG. 1B, a nanosheet stack is formed with alternating layers of semiconductor layers 110 and sacrificial layers 112 and 112A. The semiconductor layers 110 may include substantially pure silicon. The semiconductor layers 110 are the channel regions for the nanosheet FET device. The semiconductor layers 110 are nanosheets, and the nanosheets can have a thickness of, for example, 5 nanometers. The thickness of a nanosheet can range from about 2-10 nm, and other ranges are possible. The sacrificial layers 112 and 112A are formed of silicon germanium (SiGe), where germanium has an atomic percent (%) of about 25% and silicon is the remainder. In one or more embodiments, the atomic percent of germanium can range from about 15-30% while silicon is the remainder in the sacrificial layers 112 and 112A.

A hard mask layer 120 is formed on top of the semiconductor layer 110. Example materials of the hard mask layer 120 can include nitride materials such as silicon nitride.

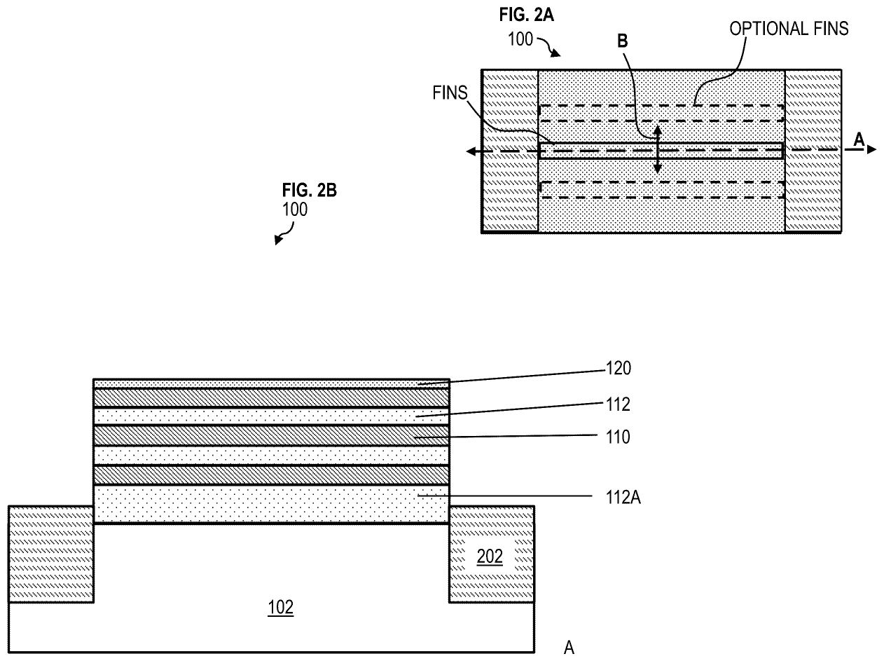

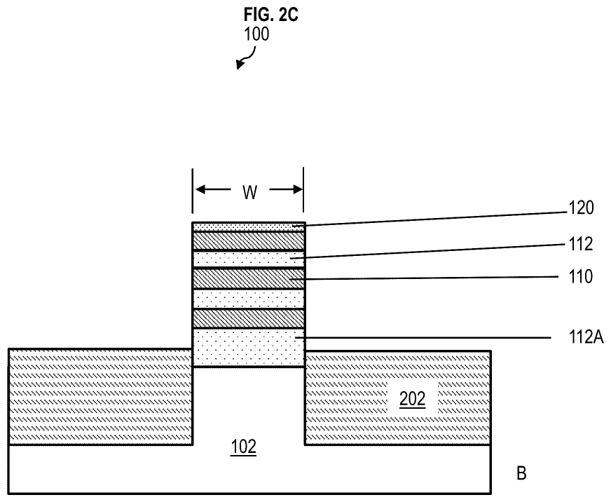

FIGS. 2A, 2B, and 2C depict the IC 100 after patterning the nanosheets into fins and shallow trench isolation formation. In addition to the cross-sectional view taken along A in FIG. 2B, FIG. 2C depicts a cross-sectional view taken along B of the IC 100.

The hard mask layer 120 is patterned, and the (patterned) hard mask layer 120 is utilized to etch the semiconductor layers 110, sacrificial layers 112 and 112A, and a portion of the substrate 102. A wet etch or dry etch may be utilized.

Shallow trench isolation (STI) regions 202 are formed in the substrate 102. Material of the STI regions 202 can include low-k dielectric materials, ultra-low-k dielectric materials, etc. As best seen in FIG. 2C, the fin width W can range from about 6-14 nm. Although a single fin is shown in FIG. 2C, there can be multiple fins which are illustrated by dashed lines in FIG. 2A.

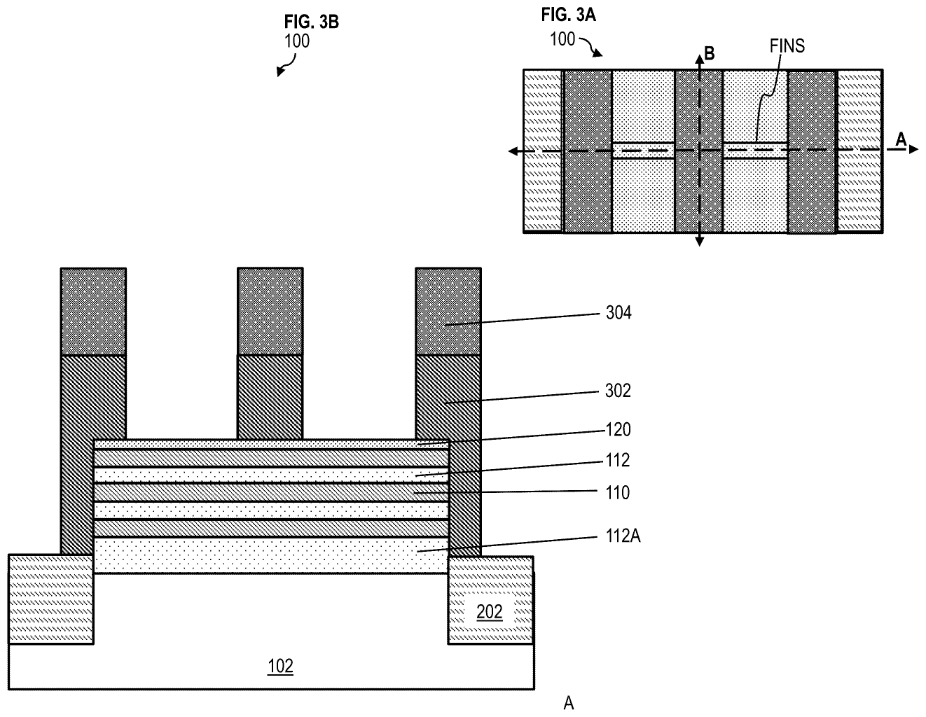

FIGS. 3A and 3B depict the IC 100 after dummy gate formation. Sacrificial gate material is formed on the IC 100 eventually resulting in dummy gates 302, and a hard mask layer 304 is formed on top of the sacrificial gate material. The hard mask layer 304 is patterned, and the (patterned) hard mask layer 304 is utilized to etch the sacrificial gate material into the dummy gates 302. The etching stops on and exposes the hard mask layer 120 and the STI regions 202. Example materials of the dummy gates 302 can include amorphous silicon, polycrystalline silicon, etc. Example materials of the hard mask layer 304 can include nitride materials such as silicon nitride, silicon oxynitride, etc.

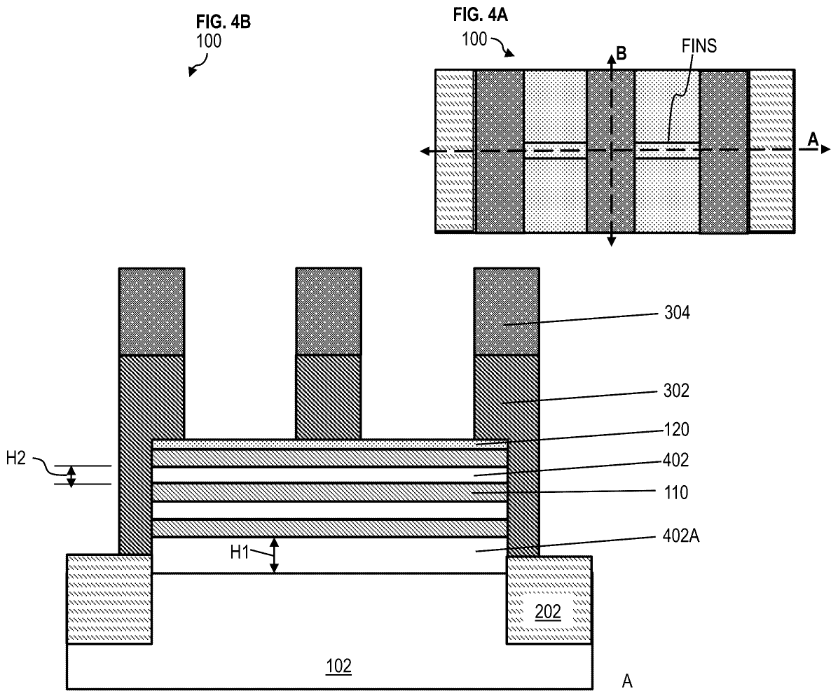

FIGS. 4A and 4B depict the IC 100 after releasing all the sacrificial layers. This is an early release of the entirety of silicon germanium material that makes the sacrificial layers 112 and 112A, thereby resulting in cavities 402 and 402A respectively. The cavity 402A has a greater height H1 than the height H2 of the cavities 402, because the sacrificial layer 112A has a greater thickness/height than the sacrificial layers 112. Unlike state-of-the-art fabrication processes, no indentation of the sacrificial layers is required to form inner spacers where the SiGe release is performed later in the fabrication process. This reduces processing steps.

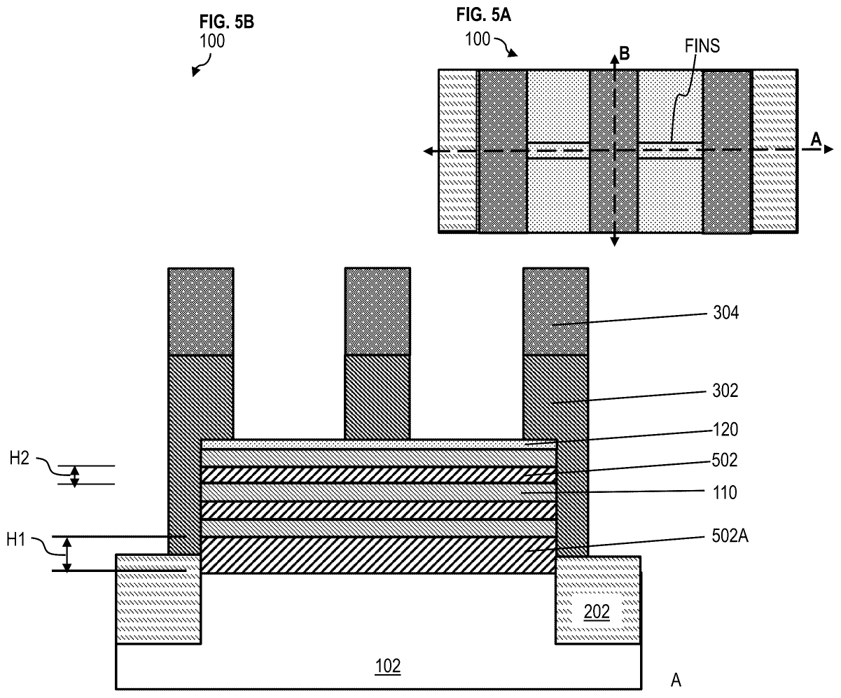

FIGS. 5A and 5B depict the IC 100 after refilling the cavities with insulating material. Deposition is performed to concurrently form hidden spacers 502 and 502A to fill in the cavities 402 and 402A. Example materials of the hidden spacers 502 and 502A may include silicon oxycarbide (SiOC), SiBCN, SiOCN, SiC, SiOCN, SiN, etc.

Etch back is performed to remove excess hidden spacer material. The bottom hidden spacer 502A is the bottom-most hidden spacer and has the thickness or height H1, while the hidden spacers 502 have the thickness or height H2. The height H1 is greater than the height H2. In one or more embodiments, height H2 is about twice (2×) the height H1. In one or more embodiments, the height H2 is about three times, four times, five times, etc., the height H1.

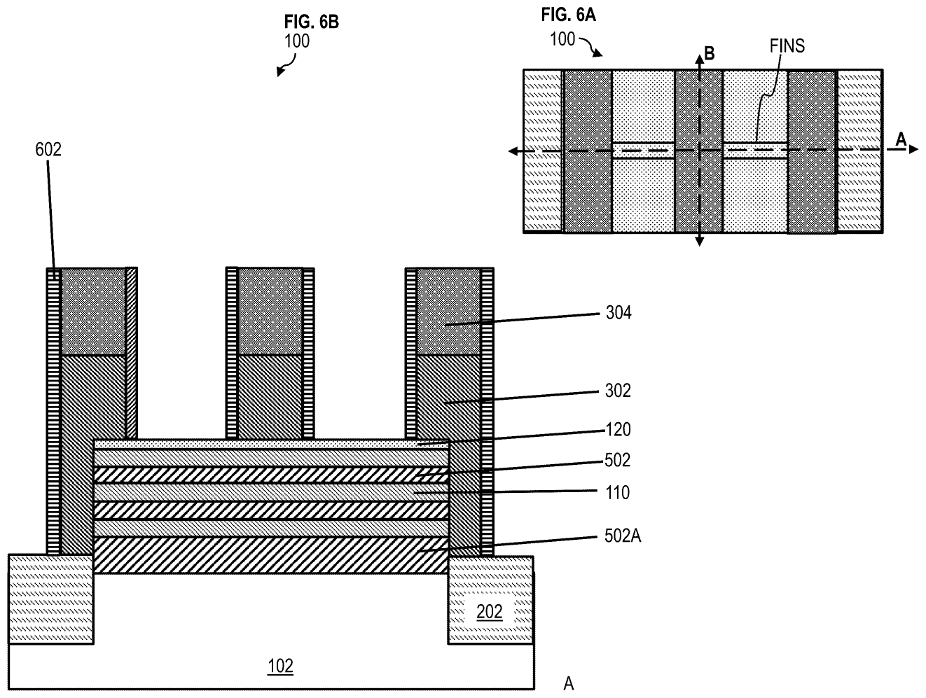

FIGS. 6A and 6B depict the IC 100 after gate spacer deposition and etching. Gate spacer material is deposited and etched to form gate spacers 602 on the dummy gates 302 and hard mask layer 304. Reactive ion etching (RIE) can be utilized to etch the deposited gate spacer material to form the gate spacers 602. Example materials of the gate spacers 602 can include nitride materials, such as SiN, SiBCN, SiOCN, SiOC, etc.

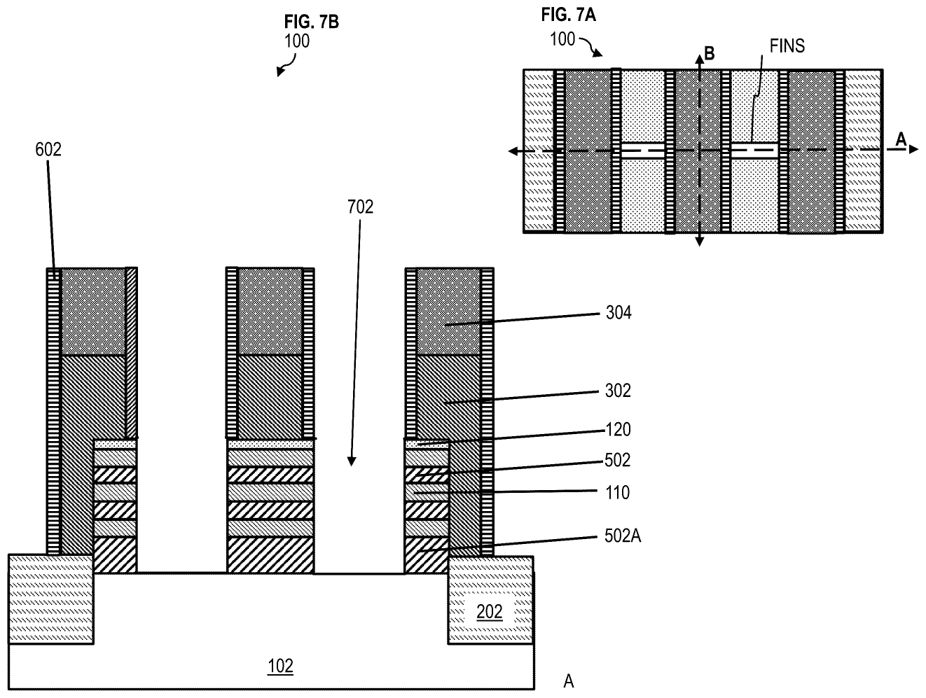

FIGS. 7A and 7B depict the IC 100 after fin recess. Directional etching is performed while using the hard mask layer 304 and gate spacers 602 as a protective mask in order to etch the fin, resulting in cavities 702. A reactive ion etch (RIE) can be utilized to etch through the hard mask layer 120, semiconductor layers 110, and hidden spacers 502 and 502A. Different etch chemistries may be utilized to etch through the different layers of the nanosheet stack, stopping on the substrate 102.

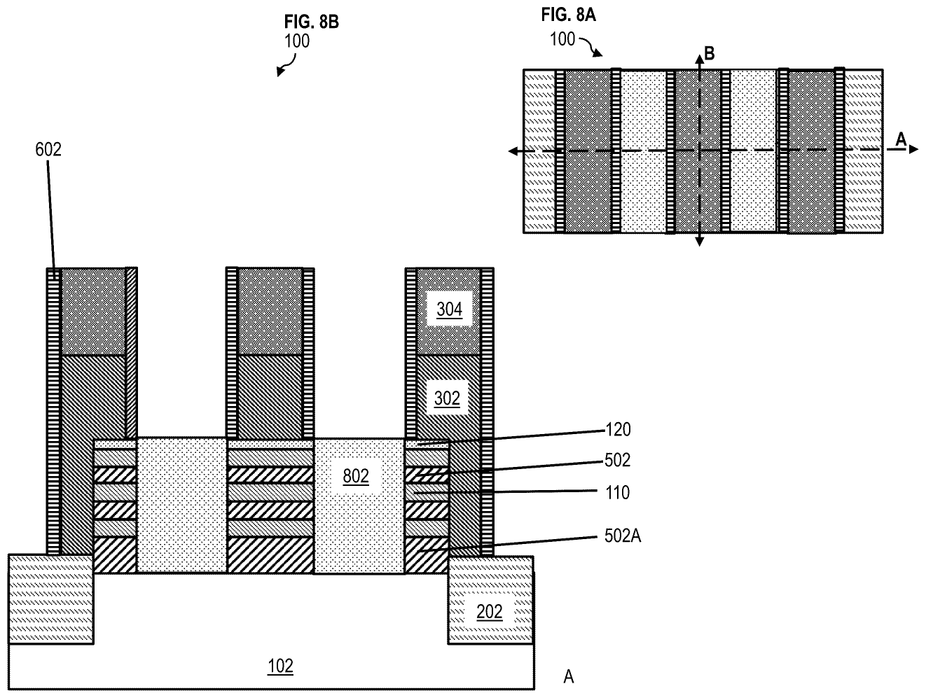

FIGS. 8A and 8B depict the IC 100 after source and drain epitaxial growth. Semiconductor material is epitaxially grown from the semiconductor layers 110 and the substrate 102. The deposited semiconductor material can be doped with n-type or p-type dopants according to whether an n-type or p-type transistor is being formed, to result in source/drain regions 802. Unlike the state-of-the-art, there is no longer a fabrication process to indent the silicon germanium sacrificial layer and fill with spacer material, because the hidden spacers 502 and 502A now serve as insulators.

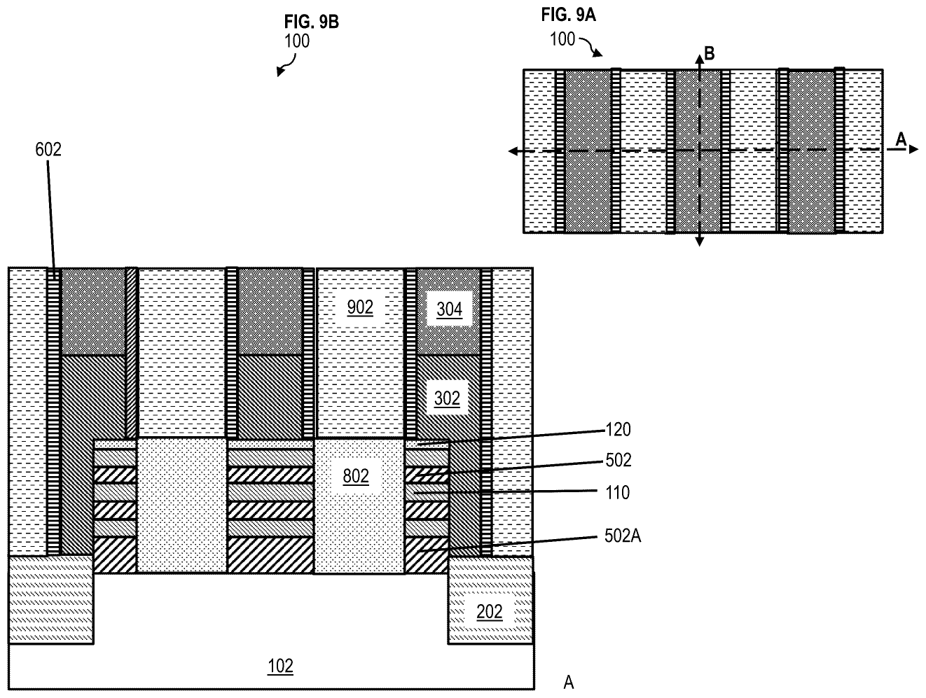

FIGS. 9A and 9B depict the IC 100 after interlayer/intralayer dielectric (ILD) formation. Fill material is deposited and polished back (e.g., using chemical mechanical polishing/planarization (CMP)) resulting in ILD layer 902. The ILD layer 902 can include low-k-dielectric materials, ultra-low-k dielectric materials, etc.

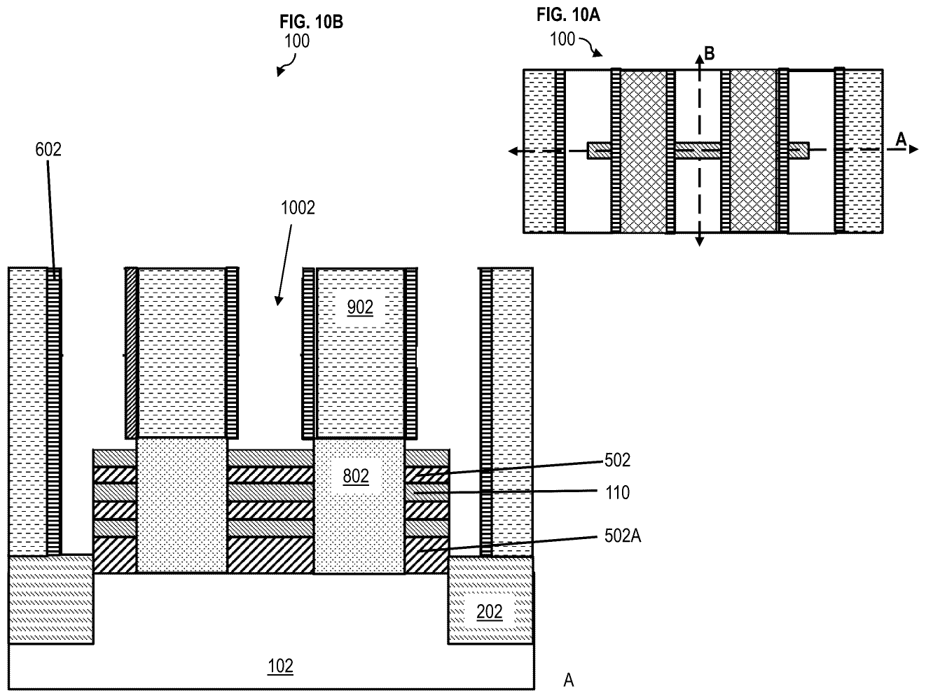

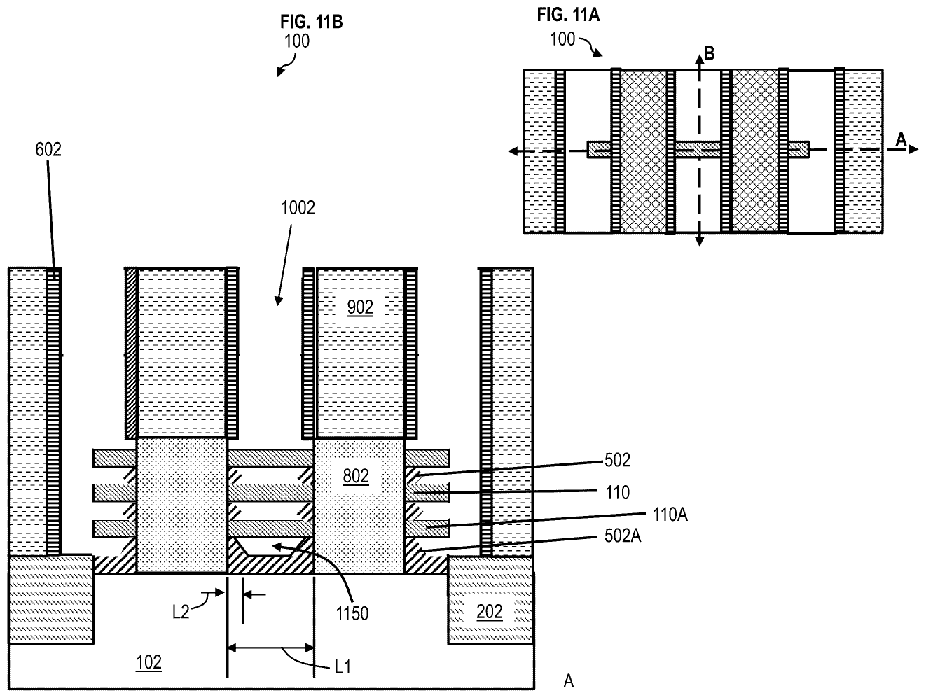

FIGS. 10A and 10B depict the IC 100 after dummy pull. The dummy gate 302 is etched after removing the hard mask layer 304, resulting in cavities 1002. The hard mask layer 120 is also removed.

FIGS. 11A and 11B depict the IC 100 after channel release. Etching is performed to remove a portion of the hidden spacers 502 and 502A. The result of the etching is to leave a portion of the hidden spacers 502 and 502A intact. The etching results in a cavity 1150 being formed in the bottom hidden spacer 502A underneath a bottom semiconductor layer 110A of the semiconductor layers 110. The bottom semiconductor layer 110A is the bottom-most semiconductor layer.

A directional etch (e.g., RIE) can be performed to etch inside and outside the screen/page. An anisotropic etch can be performed, where gas based etching or a wet based etching can be used. Further, an example vendor that provides a system for etching is Applied Materials® which supplies the Applied Centura® Sculpta® patterning system. The Applied Centura® Sculpta® patterning system makes it possible for a capability called pattern shaping, defined as precisely and unidirectionally modifying the dimensions of on-wafer features to enhance the performance of EUV patterning. The shape of the hidden spacers 502 and 502A can be tailored using the etch system to result in almost square shape or arrow tip shape.

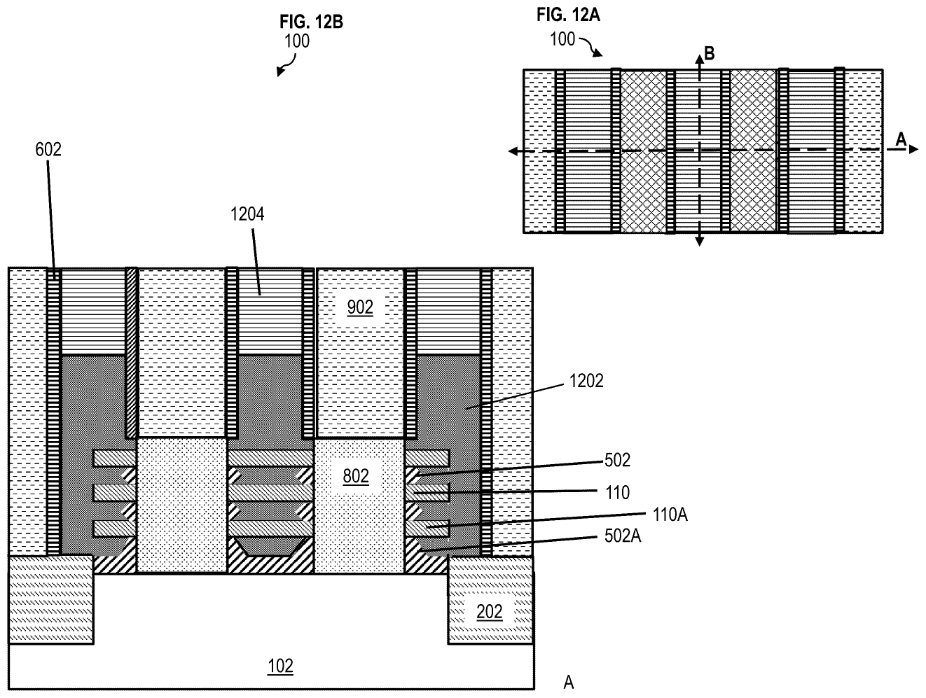

FIGS. 12A and 12B depict the IC 100 after replacement gate (RMG) formation. Gate material 1202 is formed around the semiconductor layers 110 and on the hidden spacers 502 and 502A. The gate material 1202 is in contact with the source/drain regions 802. The gate material 1202 includes a high-k dielectric layer(s) wrapped around the semiconductor layers 110. The gate material 1202 includes work function materials around the high-k dielectric layer along with a gate metal fill.

A gate cap 1204 is formed on the gate material 1202. The gate cap 1204 can include nitride materials.

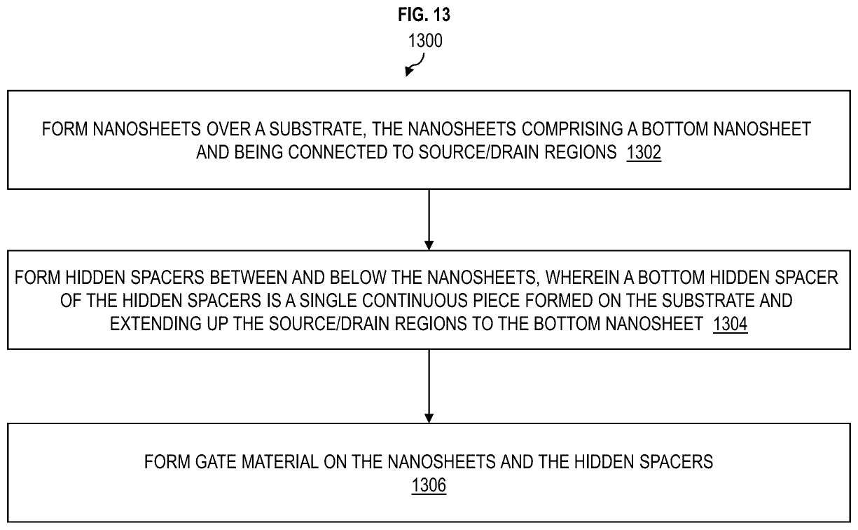

FIG. 13 is a flowchart of a method 1300 for forming an IC 100 with hidden spacers according to one or more embodiments. Reference can be made to any figures discussed herein. At block 1302, the method 1300 includes forming nanosheets (e.g., semiconductor layers 110 and sacrificial layers 112 and 112A) over a substrate 102, the nanosheets comprising a bottom nanosheet (e.g., sacrificial layer 112A) and being connected to source/drain regions 802. At block 1304, the method 1300 includes forming hidden spacers 502 (including the bottom hidden spacer 502A) between and below the nanosheets, where a bottom hidden spacer 502A of the hidden spacers 502 is a single continuous piece formed on the substrate 102 and extending up the source/drain regions 802 to the bottom nanosheet (e.g., bottom semiconductor layer 110A). At block 1306, the method 1300 includes forming gate material 1202 on the nanosheets (e.g., semiconductor layers 110) and the hidden spacers 502.

Further, the bottom hidden spacer 502A extends a length of the bottom nanosheet (e.g., bottom semiconductor layer 110A). The hidden spacers 502 include at least one other hidden spacer (e.g., hidden spacer 502) and the bottom hidden spacer 502A, the bottom hidden spacer 502A having a thickness greater than the at least one other hidden spacer (e.g., hidden spacer 502) (e.g., height/thickness H1 is greater than height/thickness H2). The hidden spacers 502 include at least one other hidden spacer and the bottom hidden spacer 502A, the bottom hidden spacer 502A having a length greater than the at least one other hidden spacer (e.g., hidden spacer 502). For example, the length L2 of bottom hidden spacer 502A (that is a continuous piece from (one) source/drain region 802 to (another) source/drain region 802) is greater than reduced length L2 of the hidden spacers 502.

Additionally, the nanosheets include alternating layers of sacrificial layers 112 and 112A and semiconductor layers 110; and forming the hidden spacers 502 between and below the nanosheets includes completely removing the sacrificial layers 112 and 112A so as to leave cavities 402 and 402A such that the hidden spacers 502 (including bottom hidden spacer 502A) are formed in the cavities 402 and 402A. The gate material 1202 is formed on a top surface of the bottom hidden spacer 502A.

Also, a cavity 1150 is formed in the bottom hidden spacer 502A, and the gate material 1202 is formed in the cavity 1150 between the top surface of the bottom hidden spacer 502A and a bottom surface of the bottom nanosheet (e.g., bottom semiconductor layer 110A). The hidden spacers 502 comprise at least one other hidden spacer and the bottom hidden spacer 502A, the at least one other hidden spacer having a square or triangular shape extending away from the source/drain regions 802. The bottom hidden spacer 502A extends between the source/drain regions 802.

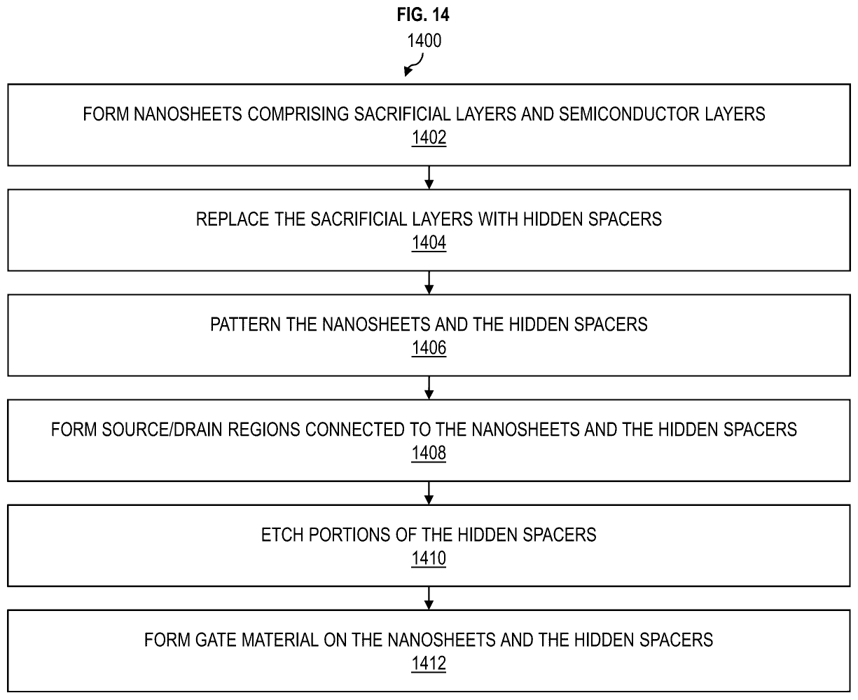

FIG. 14 is a flowchart of a method 1400 for forming an IC 100 with hidden spacers according to one or more embodiments. Reference can be made to any figures discussed herein. The method 1400 includes forming nanosheets of sacrificial layers 112 and 112A and semiconductor layers 110 at block 1402, replacing the sacrificial layers 112 and 112A with hidden spacers 502 (including bottom hidden spacer 502A) at block 1404, patterning the nanosheets and the hidden spacers 502 (including bottom hidden spacer 502A) at block 1406, and forming source/drain regions 802 connected to the nanosheets and the hidden spacers 502 (including bottom hidden spacer 502A) at block 1408. The method 1400 includes etching portions of the hidden spacers 502 (including bottom hidden spacer 502A) at block 1410 and forming gate material 1202 on the nanosheets and the hidden spacers 502 (including bottom hidden spacer 502A) at block 1412.

As discussed herein, gate material is formed around the semiconductor layers. The gate material includes high-k material and work function material generally referred to as a high-k metal gate (HKMG). Techniques for forming HKMG in gate openings are well-known in the art and, thus, the details have been omitted in order to allow the reader to focus on the salient aspects of the disclosed methods. However, it should be understood that such HKMG will generally include formation of one or more gate dielectric layers (e.g., an inter-layer (IL) oxide and a high-k gate dielectric layer), which are deposited so as to line the gate openings, and formation of one or more metal layers, which are deposited onto the gate dielectric layer(s) so as to fill the gate openings. The materials and thicknesses of the dielectric and metal layers used for the HKMG can be preselected to achieve desired work functions given the conductivity type of the FET. To avoid clutter in the drawings and to allow the reader to focus on the salient aspects of the disclosed methods, the different layers within the HKMG stack are not illustrated. For explanation purposes, a high-k gate dielectric layer can be, for example, a dielectric material with a dielectric constant that is greater than the dielectric constant of silicon dioxide (i.e., greater than 3.9). Exemplary high-k dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). Optionally, the metal layer(s) can include a work function metal that is immediately adjacent to the gate dielectric layer and that is preselected in order to achieve an optimal gate conductor work function given the conductivity type of the nanosheet-FET. For example, the optimal gate conductor work function for the PFETs can be, for example, between about 4.9 eV and about 5.2 eV. Exemplary metals (and metal alloys) having a work function within or close to this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). The optimal gate conductor work function for NFETs can be, for example, between 3.9 eV and about 4.2 eV. Exemplary metals (and metal alloys) having a work function within or close to this range include, but are not limited to, hafnium, zirconium, titanium, tantalum, aluminum, and alloys thereof, such as, hafnium carbide, zirconium carbide, titanium carbide, tantalum carbide, and aluminum carbide. The metal layer(s) can further include a fill metal or fill metal alloy, such as tungsten, a tungsten alloy (e.g., tungsten silicide or titanium tungsten), cobalt, aluminum, or any other suitable fill metal or fill metal.

Although not shown, contact formation and ILD formation are performed. ILD material can be deposited, source/drain contact openings are patterned by conventional lithography, and then metal is deposited to fill the cavities thereby forming metal contacts. A portion of the metal contacts may include silicide, resulting from the interface of the metal material and semiconductor material. The metal contacts are source/drain contacts that are respectively connected to epitaxial source/drain regions.

The ILD material can be SiO₂, SiN, a low-k dielectric material or an ultra-low-k dielectric material. Low-k dielectric materials may generally include dielectric materials having a k value of about 3.9 or less. The ultra-low-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprising:
nanosheets formed over a substrate and connected to source/drain regions, the nanosheets comprising a bottom nanosheet;
hidden spacers formed between and below the nanosheets, wherein a bottom hidden spacer of the hidden spacers is a single continuous piece formed on the substrate and extending up the source/drain regions to the bottom nanosheet; and
gate material formed on the nanosheets and the hidden spacers.

2. The semiconductor structure of claim 1, wherein the bottom hidden spacer extends a length of the bottom nanosheet.

3. The semiconductor structure of claim 1, wherein the hidden spacers comprise at least one other hidden spacer and the bottom hidden spacer, the bottom hidden spacer having a thickness greater than the at least one other hidden spacer.

4. The semiconductor structure of claim 1, wherein the hidden spacers comprise at least one other hidden spacer and the bottom hidden spacer, the bottom hidden spacer having a length greater than the at least one other hidden spacer.

5. The semiconductor structure of claim 1, wherein the gate material is formed on a top surface of the bottom hidden spacer.

6. The semiconductor structure of claim 5, wherein:
the bottom hidden spacer comprises a cavity; and
the gate material is formed in the cavity between the top surface of the bottom hidden spacer and a bottom surface of the bottom nanosheet.

7. The semiconductor structure of claim 1, wherein the hidden spacers comprise at least one other hidden spacer and the bottom hidden spacer, the at least one other hidden spacer having a square or triangular shape extending away from the source/drain regions.

8. The semiconductor structure of claim 1, wherein the bottom hidden spacer extends between the source/drain regions.

9. A method comprising:
forming nanosheets over a substrate, the nanosheets comprising a bottom nanosheet and being connected to source/drain regions;
forming hidden spacers between and below the nanosheets, wherein a bottom hidden spacer of the hidden spacers is a single continuous piece formed on the substrate and extending up the source/drain regions to the bottom nanosheet; and
forming gate material on the nanosheets and the hidden spacers.

10. The method of claim 9, wherein the bottom hidden spacer extends a length of the bottom nanosheet.

11. The method of claim 9, wherein:
the hidden spacers comprise at least one other hidden spacer and the bottom hidden spacer, the bottom hidden spacer having a thickness greater than the at least one other hidden spacer; and
the bottom hidden spacer comprises a length greater than the at least one other hidden spacer.

12. The method of claim 9, wherein:
the nanosheets comprise alternating layers of sacrificial layers and semiconductor layers; and
forming the hidden spacers between and below the nanosheets comprises completely removing the sacrificial layers so as to leave cavities such that the hidden spacers are formed in the cavities.

13. The method of claim 9, wherein the gate material is formed on a top surface of the bottom hidden spacer.

14. The method of claim 13, wherein:
a cavity is formed in the bottom hidden spacer; and
the gate material is formed in the cavity between the top surface of the bottom hidden spacer and a bottom surface of the bottom nanosheet.

15. The method of claim 9, wherein the hidden spacers comprise at least one other hidden spacer and the bottom hidden spacer, the at least one other hidden spacer having a square or triangular shape extending away from the source/drain regions.

16. The method of claim 9, wherein the bottom hidden spacer extends between the source/drain regions.

17. A semiconductor structure comprising:
nanosheets formed over a substrate and connected to source/drain regions, the nanosheets comprising a bottom nanosheet;
hidden spacers formed between and below the nanosheets, wherein a bottom hidden spacer of the hidden spacers is a single continuous piece formed on the substrate and extending up the source/drain regions to the bottom nanosheet, wherein the bottom hidden spacer comprises a cavity below the bottom nanosheet; and
a gate material formed on the nanosheets and the hidden spacers, the gate material filling the cavity of the bottom hidden spacer.

18. The semiconductor structure of claim 17, wherein the bottom hidden spacer extends a length of the bottom nanosheet.

19. The semiconductor structure of claim 17, wherein the hidden spacers comprise at least one other hidden spacer and the bottom hidden spacer, the bottom hidden spacer having a thickness greater than the at least one other hidden spacer.

20. The semiconductor structure of claim 17, wherein the hidden spacers comprise at least one other hidden spacer and the bottom hidden spacer, the bottom hidden spacer having a length greater than the at least one other hidden spacer.

21. The semiconductor structure of claim 17, wherein the gate material is formed on a top surface of the bottom hidden spacer.

22. The semiconductor structure of claim 21, wherein the gate material is formed in the cavity between the top surface of the bottom hidden spacer and a bottom surface of the bottom nanosheet.

23. The semiconductor structure of claim 17, wherein the hidden spacers comprise at least one other hidden spacer and the bottom hidden spacer, the at least one other hidden spacer having a triangular shape extending away from the source/drain regions.

24. The semiconductor structure of claim 17, wherein the bottom hidden spacer extends between the source/drain regions.

25. A method comprising:
forming nanosheets comprising sacrificial layers and semiconductor layers;
replacing the sacrificial layers with hidden spacers;
patterning the nanosheets and the hidden spacers;
forming source/drain regions connected to the nanosheets and the hidden spacers;
etching portions of the hidden spacers; and
forming gate material on the nanosheets and the hidden spacers.
